(19) United States
(12) Patent Application Publication
(10) Pub. No.: US 2007/0199657 A1
(43) Pub. Date: Aug. 30, 2007

(54) Apparatus and method for plasma etching

(76) Inventors: Naoyuki Kofuji, Tokyo (JP); Hiroshi Akiyama, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/500,360

(22) Filed: Aug. 8, 2006

(30) Foreign Application Priority Data
Feb. 28, 2006 (JP) 2006-052725

(51) Int. Cl. H01L 21/306; C23F 1/00

(52) U.S. Cl. 156/345.24; 438/710; 438/714; 216/59; 156/345.26; 156/345.25

(57) ABSTRACT

The invention aims at solving the problems of throughput deterioration, reproducibility deterioration and plasma discharge instability when performing continuous discharge during multiple steps of plasma etching. According to the present invention, the gas supply unit is operated while determining the timing for switching conditions of a plurality of plasma etching steps, and the gas flow rate and gas pressure are controlled so that the pressure of processing gas supplied from the gas supply unit to the processing chamber does not fall below a predetermined pressure immediately subsequent to switching steps. For example, upon switching processing gases, the end point of a step is predicted based on an interference film thickness meter, and prior to the end point by two seconds or more, the flow rate of MFC is set to the gas flow rate for the subsequent step and the gas is flown to the exhaust device, so that simultaneously as when the end point signal is received, the processing gases are switched by switching valves.

The present application is based on and claims priority of Japanese patent application No. 2006-52725 filed on Feb. 28, 2006, the entire contents of which are hereby incorporated by reference.

### BACKGROUND OF THE INVENTION

1. Field of the Invention

The present invention relates to a plasma etching apparatus and a plasma etching method for etching semiconductor devices, and more specifically, relates to a plasma etching apparatus and a plasma etching method for performing continuous discharge having reduced etching defects and improved processing speed.

2. Description of the Related Art

We will first describe the transitions seen with respect to the plasma etching process used for processing gates of semiconductor devices. Until the early 1990s, single-layer Poly-Si (polysilicon) films were used as gate electrodes. Therefore, methods for processing devices under a single etching condition were mainly adopted (refer for example to non-patent reference 1: S. K. KIM et al., “Investigation of ECR plasma and its Silicon Etching at LN2 Temperature in SF6”, Proceedings of symposium on Dry process 1992, P. 39-42).

In the late 1990s when gates having laminated structures composed of different materials have been introduced, processes performed under a single condition were no longer sufficient, and new methods for processing the substrates under multiple conditions via multiple steps were introduced (refer for example to non-patent reference 2: H. Ootera et al., “Highly Selective Etching of W/WN/poly-Si Gate on Thin Oxide Film with Gaspuff Plasmas”, Proceedings of symposium on Dry process 1999, P. 155-160). In this method, the gas flow rate and gas pressure were fluctuated for ten or more seconds immediately after switching conditions. In order to prevent deterioration of reproducibility caused by performing gate etching under such uncertain condition during fluctuation, a method to discontinue plasma discharge when transiting from one step to another (intermittent discharge) was introduced.

However, this method had two drawbacks. One problem was the deterioration of throughput. Since it took ten or more seconds to switch conditions, the increase in the switching of conditions lead to increase of processing time. The other problem was the increased product defects. Usually, a large amount of particles is generated within the processing chamber during etching. These particles are trapped in the portion called an ion sheath existing at the boundary between the plasma and wafer during plasma discharge, but the instant the plasma discharge is discontinued, the particles are adhered onto the wafer.

In the former process performed under a single condition, the particles were trapped in the sheath, and instantaneously when the etching was completed and plasma discharge was discontinued, they were adhered onto the wafer. The particles adhered on the wafer were removed through cleaning, so actually very little product defects occurred.

On the other hand, in the process where discharge is performed intermittently, the particles are adhered on the wafer during the etching process by the ceased discharge. When the etching is resumed, the areas immediately under the adhered particles remain unetched. Therefore, even when the particles are removed through cleaning, the unetched portions remain and cause product defects.

In order to reduce product defects, some semiconductor device makers are considering methods to not cease discharge, that is, to perform continuous discharge, when transiting from one step to another.

Most continuous discharge methods provide an intermediate step between one step and another, during which time the etching is suppressed during switching of gases by diluting the gas with rare gas having small reactivity. However, even by adopting this method, the gas switching time will not be reduced, and thus, the deterioration of throughput cannot be prevented.

In order to improve throughput, it is necessary to perform continuous discharge without adopting intermediate steps. In such case, in order to improve the reproducibility, it is necessary to reduce as much as possible the time during which the flow rate and pressure are fluctuated immediately subsequent to switching conditions.

One method for suppressing fluctuation of flow rate immediately subsequent to switching gases is to have the gas flown through an exhaust line before introducing the same to the processing chamber by switching valves (refer for example to the prior art disclosed in patent reference 1: Japanese Patent Application Laid-Open Publication No. 5-198513). The actual structure of the prior art is shown in FIG. 41. An exhaust gas line 9 connecting an MFC (mass flow controller) 3 and an exhaust pump 5 is disposed independently from the processing gas line 8 connecting the gas supply source 4, the MFC 3, the processing chamber 6 and the exhaust pump 7, and valves 1 and 2 are disposed on each of the gas lines. Upon supplying gas, valve 2 is opened while valve 1 is closed, and the flow rate Qo of MFC 3 is set to the same value as the flow rate Q for processing, so as to have gas flown to the exhaust pump 5. When the flow rate Qo is stabilized, valve 2 is closed and valve 1 is opened simultaneously, according to which gas can be supplied without causing overshoot.

Further, another method is disclosed to set the flow rate Qo flown in the exhaust gas line to be smaller than the flow rate Q for processing, in order to prevent minute overshoot at the start of the gas supply caused by the difference in conductance of the exhaust gas line 9 and the processing gas line 8 (refer for example to patent reference 1).

On the other hand, regarding fluctuation of pressure, it is normal to adopt a method to dispose a variable valve between the exhaust pump 7 and the processing chamber 6, and to perform feedback control of the measured value of a pressure meter to the opening of the variable valve, so as to maintain the pressure of the processing chamber 6 to a desired value.

In order to perform continuous discharge in a plasma etching process without adopting intermediate steps, it is necessary for the gas flow rate and the gas pressure being mutually related to be switched smoothly and in a short period of time. However, though there were means according to the prior art to realize a high-speed control of the gas flow rate or the stability control of pressure, there were no means taking into consideration the interaction of gas flow rate and gas pressure. Therefore, there were drawbacks in that the gas flow rate or gas pressure became instantaneously unstable immediately subsequent to switching conditions. If continuous discharge is performed under such condition, the plasma will be extinguished immediately subsequent to switching conditions. When plasma is extinguished, the particles will adhere to the wafer, making it difficult to reduce product defects.

### SUMMARY OF THE INVENTION

The object of the present invention is to provide a plasma etching apparatus capable of controlling the gas flow rate and the gas pressure in order to prevent the plasma from being extinguished when performing continuous discharge in the plasma etching process.

The plasma etching apparatus according to the present invention characterizes in determining the timing for switching conditions for multiple steps and operating the gas supply unit accordingly, and controlling the gas flow rate and the gas pressure so that the pressure of the processing gas introduced to the processing chamber from the gas supply unit does not fall to or below a predetermined pressure immediately subsequent to switching steps.

According to the present invention, the plasma etching process can be performed via continuous discharge without adopting intermediate steps, so the throughput of the process is improved. Further, since according to the present invention the discharge does not become unstable during switching of steps, product defects caused by particles can be reduced significantly.

### BRIEF DESCRIPTION OF THE DRAWINGS

FIG. 1 is a configuration diagram of an etching apparatus according to embodiment 1 of the present invention;

FIG. 2 shows a structure of a gas supply unit of the etching apparatus according to embodiment 1;

FIG. 3 shows a plasma discharge stable range when the ratio of power is 1:1 according to embodiment 1;

FIG. 4 shows a plasma discharge stable range when the ratio of power is 1:0 according to embodiment 1;

FIG. 5 shows a plasma discharge stable range when the ratio of power is 0:1 according to embodiment 1;

FIG. 6 is an etching condition chart according to embodiment 2 of the present invention;

FIG. 7 shows a time variation of the total gas flow rate of the first wafer according to embodiment 1;

FIG. 8 shows a time variation of the total gas flow rate of the second wafer according to embodiment 1;

FIG. 9 shows the structure of a gas supply unit of the etching apparatus according to embodiment 2;

FIG. 10 shows a time variation of the total gas flow rate of the first wafer according to embodiment 2;

FIG. 11 shows a time variation of the total gas flow rate of the second wafer according to embodiment 2;

FIG. 12 shows a time variation of the reflecting power of embodiment 2;

FIG. 13 shows a time variation of the vacuum processing chamber pressure of embodiment 2;

FIG. 14 is a configuration diagram of the etching apparatus according to embodiment 3 of the present invention;

FIG. 15 shows a time variation of reflection intensity obtained via an interference film thickness monitor according to embodiment 3;

FIG. 16 shows a time variation of the total gas flow rate according to embodiment 3;

FIG. 17 shows a time variation of the vacuum processing chamber pressure according to embodiment 3;

FIG. 18 shows a time variation of the reflecting power according to the present invention;

FIG. 19 shows a time variation of the total gas flow rate according to embodiment 3 of the present invention;

FIG. 20 shows a time variation of the vacuum processing chamber pressure according to embodiment 3;

FIG. 21 shows a time variation of the reflecting power according to embodiment 3;

FIG. 22 shows a time variation of the vacuum processing chamber pressure according to embodiment 3;

FIG. 23 is a configuration diagram of the etching apparatus according to embodiment 4 of the present invention;

FIG. 24 shows the relationship between a valve opening control cycle and a pressure minimal value according to embodiment 4;

FIG. 25 shows a time variation of the vacuum processing chamber pressure according to embodiment 4;

FIG. 26 shows a time variation of the reflecting power according to embodiment 4;

FIG. 27 is a configuration diagram of the etching apparatus according to embodiment 5 of the present invention;

FIG. 28 is an etching condition chart according to embodiment 5;

FIG. 29 is a cross-sectional structure of the substrate to be etched prior to processing according to embodiment 5;

FIG. 30 is a cross-sectional structure of the substrate to be etched immediately subsequent to step 2 according to embodiment 5;

FIG. 31 is a cross-sectional structure of the substrate to be etched immediately subsequent to step 3 according to embodiment 5;

FIG. 32 shows a time variation of the vacuum processing chamber pressure in the case of intermittent discharge;

FIG. 33 shows a time variation of the input reflecting power of microwaves in the case of intermittent discharge;

FIG. 34 shows a time variation of vacuum processing chamber pressure in the case of continuous discharge;

FIG. 35 shows a time variation of the input reflecting power of microwaves in the case of continuous discharge;

FIG. 36 shows the relationship between the vacuum processing chamber pressure and the etching rate of silicon and silicon oxide film according to the condition of step 3;

FIG. 37 shows a time variation of the total gas flow rate according to embodiment 6 of the present invention;

FIG. 38 shows a time variation of the total gas flow rate according to embodiment 6;

FIG. 39 is a time variation of the vacuum processing chamber pressure according to embodiment 6;

FIG. 40 is a cross-sectional structure of the substrate to be etched immediately subsequent to step 3 according to embodiment 6; and

FIG. 41 shows a structure of a gas supply unit according to the prior art example of patent document 1.

### DETAILED DESCRIPTION OF THE PREFERRED EMBODIMENTS

Now, the preferred embodiments for carrying out the present invention will be described with reference to the drawings.

### Embodiment 1

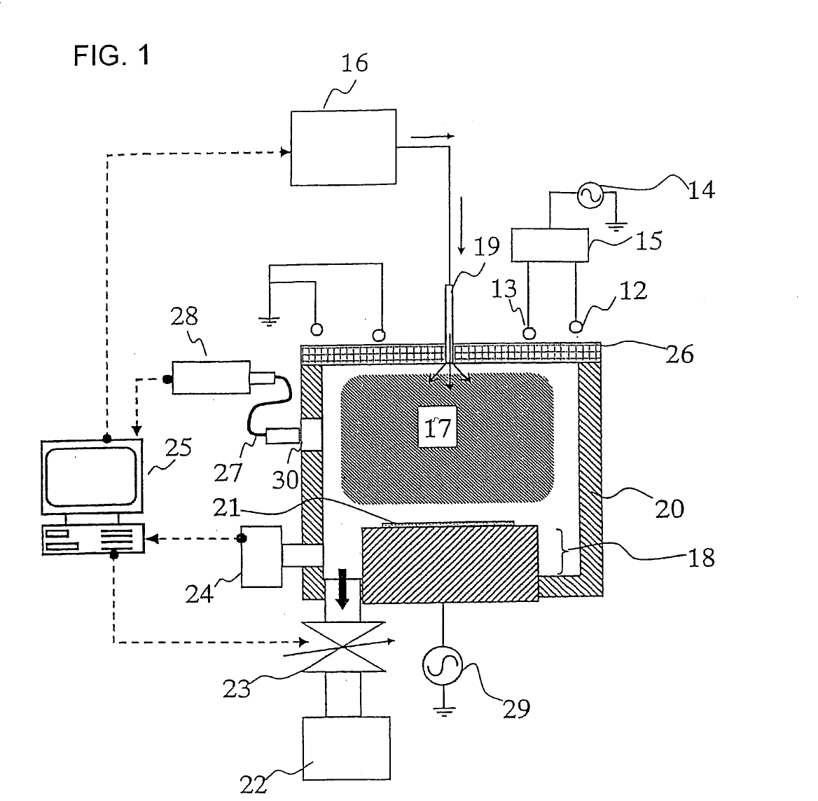

The structure of an etching apparatus according to embodiment 1 of the present invention is illustrated in FIG. 1. In this apparatus, etching gas is supplied from a gas supply unit 16 via a gas nozzle 19 into a vacuum processing chamber 20, and an RF power of 13.56 MHz is applied from an RF (high frequency) power supply 14 to antenna coils 13 and 12 disposed outside a dielectric window 26 formed of alumina, to thereby generate inductively coupled plasma 17 from the etching gas.

A power distributor 15 is disposed between the antenna coils 12 and 13 and the RF power supply 14, so as to control the distribution of the generated plasma by adjusting the ratio of power supply to the antenna coils 12 and 13. The etching process is performed by irradiating plasma to a wafer 21 mounted on a wafer stage 18. An RF power supply 29 is connected to the wafer stage 18, and the wafer 21 is etched effectively by applying an RF power of 13.56 MHz thereto.

Furthermore, the pressure of the vacuum processing chamber 20 can be controlled via a turbo-molecular pump 22 and a pressure controlling variable valve 23. The pressure is measured by a capacitance manometer 24 disposed above the variable valve 23.

In order to maintain the pressure at a desired value, a computer 25 controlling the whole system performs sampling of the pressure once every 0.2 s (seconds) and performs feedback control of the opening of the variable valve 23. The time required for opening and closing the variable valve is 1.0 s (seconds). The inner volume of the vacuum processing chamber is set relatively small to 60 L (liters) so as to enhance the response of pressure control.

A quartz window 30 is disposed on the side wall of the processing chamber, to which is connected a spectroscopy system 28 via an optical fiber 27, for analyzing the plasma emission and determining the timing for switching conditions. Based on the instruction to switch conditions from the spectroscopy system 28, the computer instructs the next conditions to various units of the apparatus such as the gas supply unit 28.

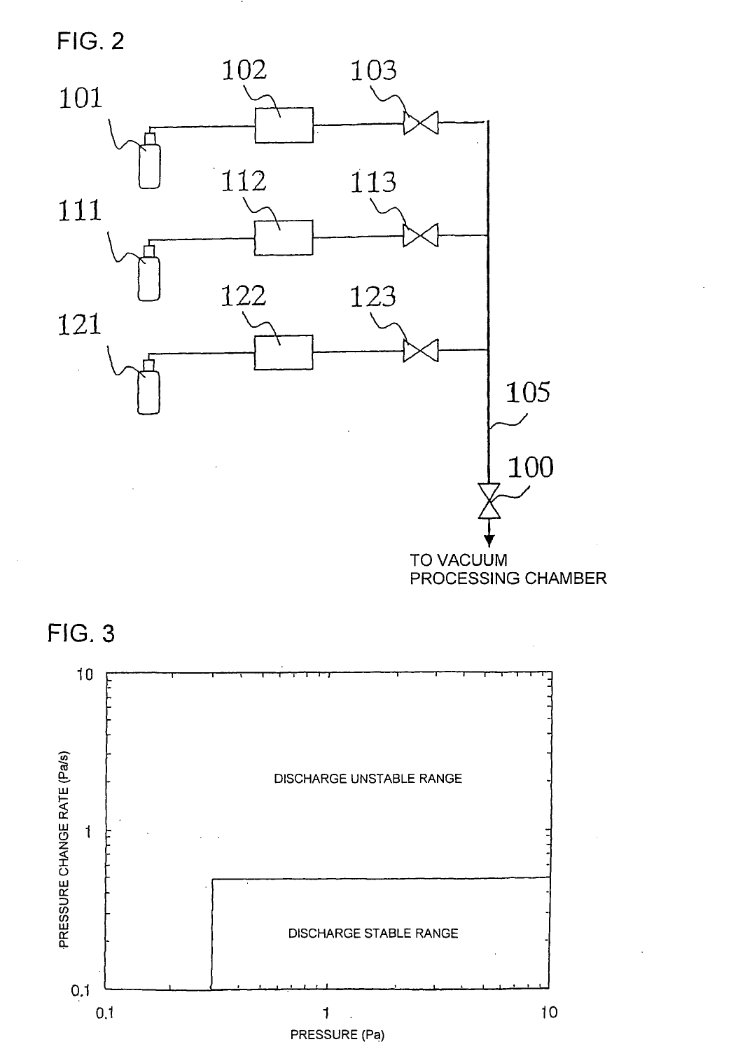

In embodiment 1 of the present invention, a gas supply unit 16 illustrated in FIG. 1 adopts a structure used in a standard plasma etching apparatus as illustrated in FIG. 2. MFCs 102, 112 and 122 and valves 103, 113 and 123 are attached to each of the gas lines, and the gas lines are all connected at the downstream side of the valve, which is introduced via a valve 100 to the processing chamber. FIG. 2 shows an example in which three gas lines are used, but the number is not limited to three, and multiple number of gas lines can be used to switch and change the conditions of multiple gases.

Now, an ordinary gas switching sequence will be described, taking as an example an operation for switching from gas 101 to gas 112. In the step using gas 101, the flow rate of the MFC 102 attached to the gas line of gas 101 is set to a desired value, and the valves 103 and 100 attached to the processing gas line 105 connecting the MFC 102 and the vacuum processing chamber are opened. All the other valves are closed, and the flow rate of other MFCs are set to 0 sccm (standard cc/min) Simultaneously as when the signal for switching conditions is entered, the flow rate of the MFC 102 is set to 0 sccm, valve 103 is closed, and valve 113 is opened. At the same time, the flow rate of the MFC 112 of gas 111 is set to a desired value.

Next, the operation for changing the flow rate will be described, taking as an example an operation for changing the flow rate of gas 101. In the former step, the valves 103 and 100 are opened, and the flow rate of the MFC 102 is set to Q1. Simultaneously when the instruction to switch conditions is output, the value of MFC 102 is set to Q2.

Upon performing continuous discharge using the present apparatus, it is necessary to maintain stable discharge even when the pressure is varied among steps. Therefore, the margin corresponding to the plasma pressure change regarding plasma stability is examined by a method for monitoring reflecting power.

FIGS. 3 through 5 illustrate the result of examining a discharge stable area and a discharge unstable area when the power ratio of the inner antenna coil 13 and the outer antenna coil 12 shown in FIG. 1 is set to 1:1, 1:0 and 0:1, respectively.

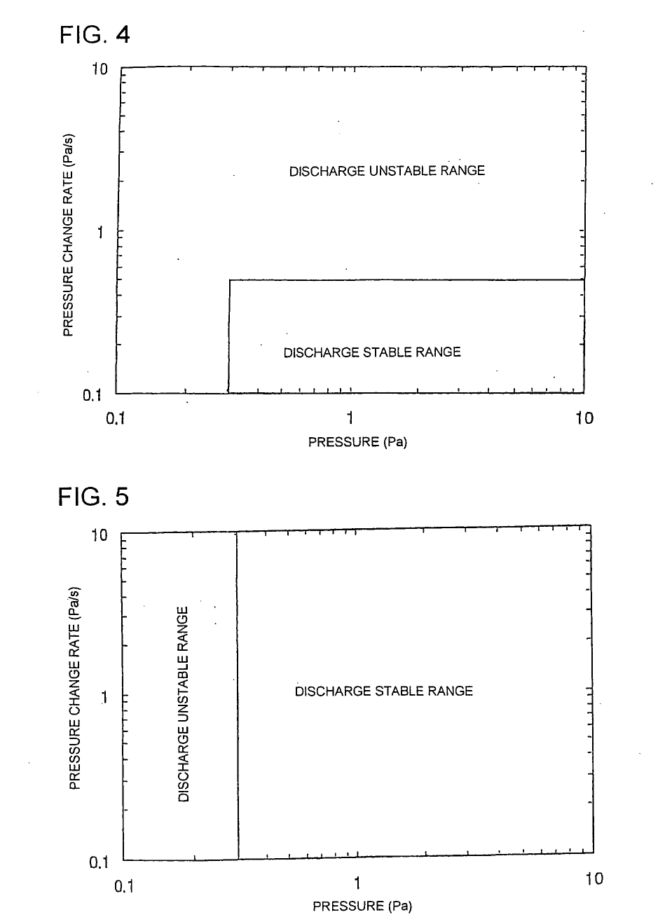

It can be seen that when the power ratio of the inner antenna coil 13 and the outer antenna coil 12 was set to 1:1 and 1:0, the discharge was unstable when the pressure was set to a low pressure condition of 0.3 Pa or lower, and the discharge was also unstable then the rate of pressure change was 0.5 Pa/s (Pascal/second) or greater (refer to FIGS. 3 and 4).

On the other hand, when the power ratio of the inner antenna coil 13 and the outer antenna coil 12 was set to 0:1, it has been found that the reflecting power was increased in the area where the pressure was 0.3 Pa and smaller, and plasma was extinguished (refer to FIG. 5). In this case, however, if the pressure was greater than 0.3 Pa, the discharge maintained a stable condition even when the rate of pressure change was varied.

Based on the above experiment results, it has been discovered that in all the cases, the discharge entered an unstable area when the pressure was equal to or below a given pressure (0.3 Pa), so upon performing continuous discharge, in order to maintain a stable discharge when conditions are changed between steps, it is necessary to control the gas flow rate and gas pressure so that the gas pressure immediately subsequent to switching steps does not fall to the predetermined pressure. Furthermore, in order to cope with the change in pressure immediately subsequent to switching steps, it is preferable to supply power from the outer antenna coil 12.

Therefore, according to embodiment 1 of the present invention, the gas flow rate and the gas pressure are controlled so that the gas pressure immediately subsequent to switching steps does not fall to or below a predetermined pressure, and at the same time, the power ratio is set to 0:1 according to which the margin for variation in the rate of pressure change is great, during the period immediately subsequent to switching steps when the pressure variation is great, or in other towards, power is supplied only through the outer antenna coil 12 and the power of the inner antenna coil 13 is set to 0 during the period immediately subsequent to switching steps when the pressure fluctuation is great.

According to embodiment 1 of the present invention, the gas pressure immediately subsequent to switching steps is controlled to be greater than the given pressure, and the power is supplied only through the outer antenna coil 12, so that the discharge stable condition can be maintained effectively even during the rapid change in gas pressure immediately subsequent to switching steps.

### Embodiment 2

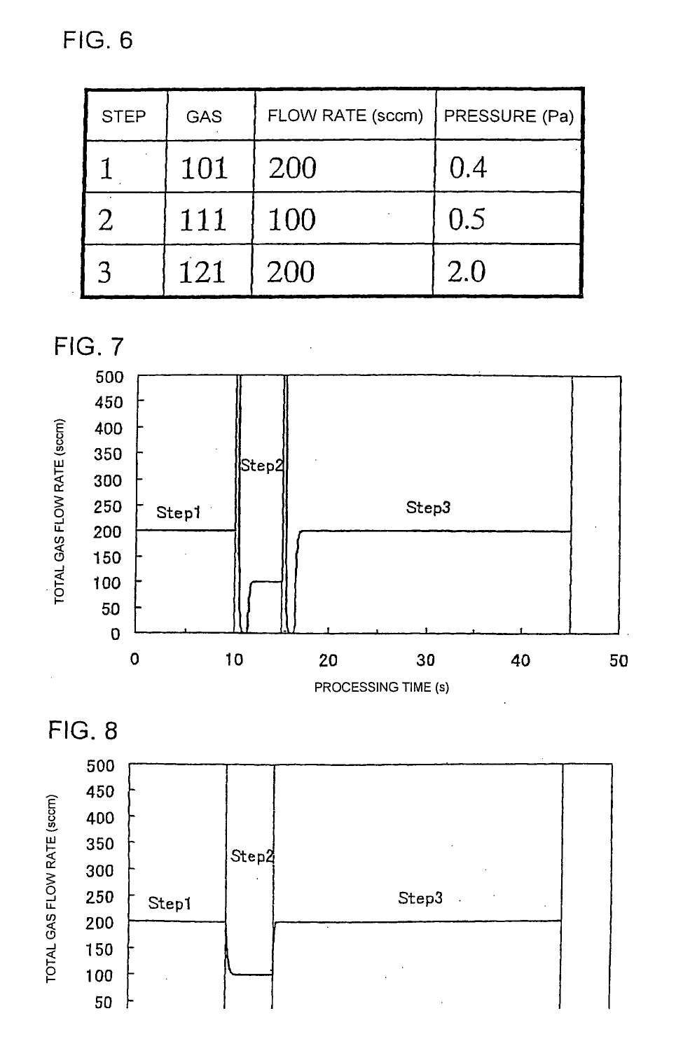

When utilizing the method of embodiment 1 to continuously process two wafers by performing continuous discharge while switching the types of gases, the flow rates of gases and the pressures of gases according to a three-step etching shown in FIG. 6, there had been discovered a phenomenon in which the finished sizes of the first wafer and the second wafer differ greatly.

FIG. 7 shows the time variation of the total gas flow rate during processing of the first wafer, and FIG. 8 shows the time variation of the total gas flow rate for the second wafer. In the wafer processing of the first wafer shown in FIG. 7, during the first three seconds of the start of flow of the second gas 111 and the first three seconds of the start of flow of the third gas 121, the gas flow rate varied greatly and became unstable. In contrast, during processing of the second wafer shown in FIG. 8, such unstable gas flow rate is not seen during the start of flow of gas 111 or the start of flow of gas 121. This is considered to cause the difference in finished size of the first and second wafers.

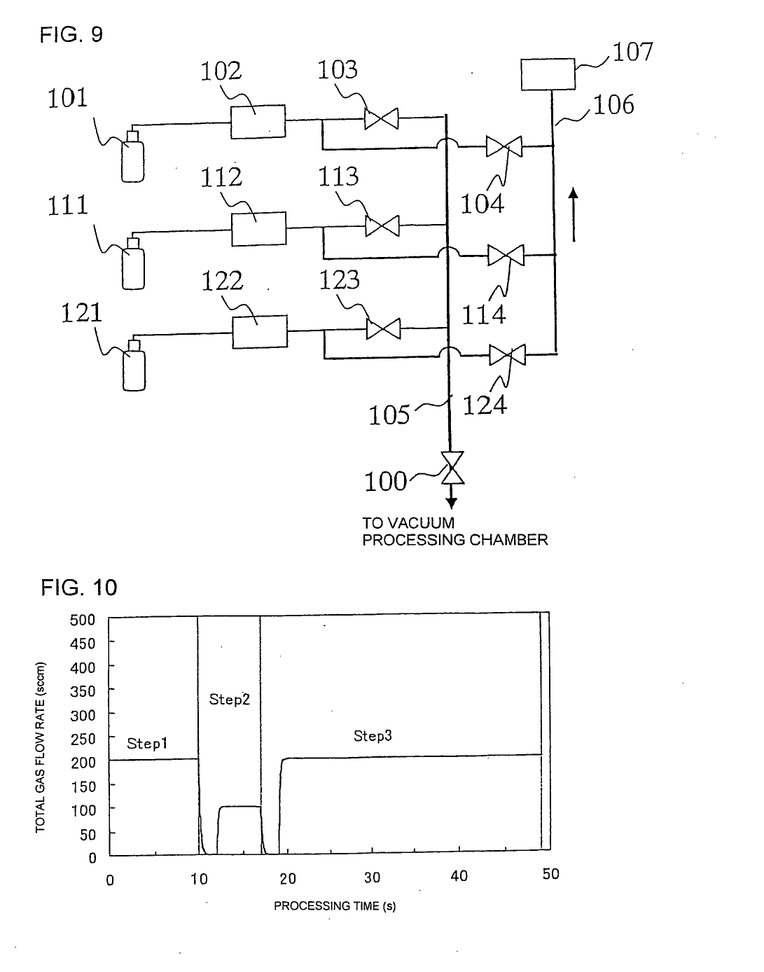

The finished sizes of the second and subsequent wafers are the same according to the method of embodiment 1, but in embodiment 2 of the present invention, in order to improve the reproducibility even further, the gas flow rate control method disclosed in the prior art of patent reference 1 is adopted. The structure of the gas supply unit of this example is shown in FIG. 9. The difference from the gas supply unit 16 shown in FIG. 2 of embodiment 1 is that exhaust gas lines 106 connected to an exhaust pump 107 are additionally installed between MFC 102 and valve 103, MFC 112 and valve 113, and MFC 122 and valve 123, with valves 104, 114 and 124 attached respectively thereto.

The present embodiment using this gas supply unit will now be described, taking as an example the operation for switching from gas 101 to gas 121.

In the step using gas 101, the flow rate of MFC 102 connected to the gas line of gas 101 is set to a desirable value, and the valves 103 and 100 mounted to the processing gas line 105 communicating the MFC 102 and the vacuum processing chamber are opened. Further, other valves are all closed, and the flow rates of other MFCs are set to 0 sccm. Simultaneously when the signal for switching conditions is entered, the flow rate of MFC 102 is set to 0 sccm and the valve 103 is closed. At the same time, the valve 114 is opened, and the flow rate of MFC 112 of gas 111 is set to a desired value. When the flow rate of MFC 112 becomes stable, the valve 113 of the processing gas line is opened and the valve 114 is closed. In addition, if only the gas flow rate is to be changed, the same sequence as the prior art method is adopted.

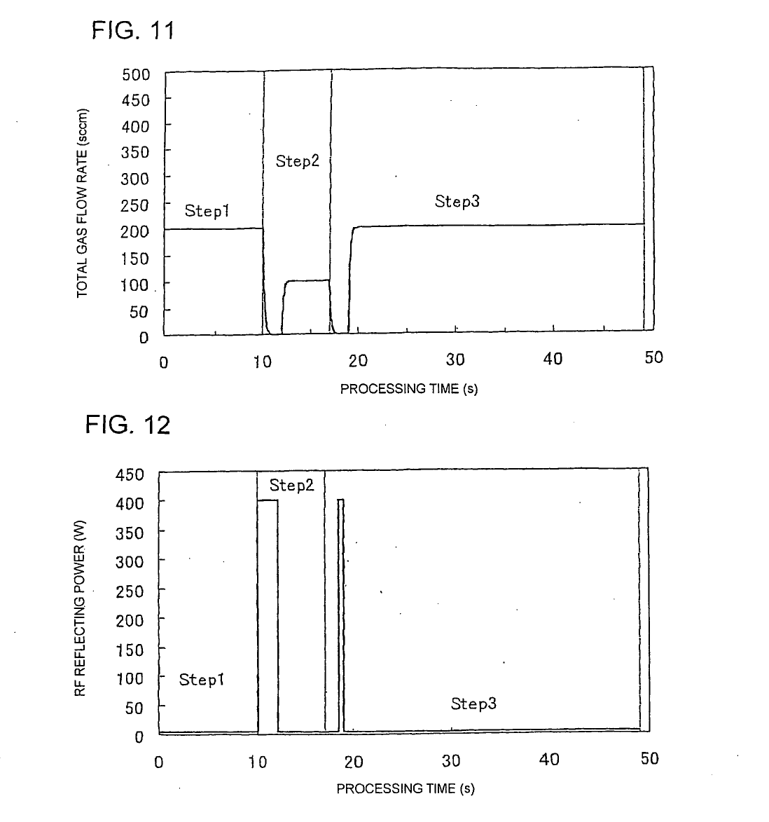

The result of variation of total gas flow rate for the first wafer according to the case in which the gas switching method described above is applied to the three-step etching of FIG. 6 is shown in FIG. 10, and the result for the second wafer is shown in FIG. 11. Unstable gas flow rate was not seen for both the first and second wafers, and the reproducibility was improved. Furthermore, the reproducibility of the processing dimension was improved.

According to embodiment 2 of the present invention, the gas supply unit illustrated in FIG. 9, in other words, the gas supply unit having exhaust gas lines leading to an exhaust pump added to each of the gas supply lines, is used as the gas supply unit 16, and upon switching conditions, the flow rate of the former MFC is set to 0 and the valve thereof is closed, while the exhaust valve of the subsequent gas is opened and the flow rate of the MFC of the subsequent gas is set to a desired value, and when the flow rate of MFC is stabilized, the valve of the processing gas line is opened and the exhaust valve thereof is closed simultaneously. According to embodiment 2, there is no instability during switching, and the reproducibility of the process is improved.

### Embodiment 3

According to the system of embodiment 2, it is possible to perform continuous discharge having an improved reproducibility without any instability during switching of conditions including the processing of first and second wafers, but even according to the system of embodiment 2, there were cases in which the finished product was defective.

The product defectiveness of the wafer was examined in detail, and it has been found that the product defect rate caused by particles when the system of embodiment 2 was used to perform continuous discharge sometimes even reached 70%, which is equivalent to the case in which the discharge was performed intermittently.

With the aim to solve the above-mentioned problem, FIG. 12 shows the result of examination of the time variation of reflecting power with respect to the example of FIG. 10. In FIG. 12, it can be seen that the reflective power is instantaneously increased immediately subsequent to transiting from step 1 to step 2 and switching from gas 101 to gas 111, and immediately subsequent to transiting from step 2 to step 3 and switching from gas 111 to gas 121, which shows that there are cases in which the plasma is instantaneously extinguished immediately subsequent to switching gases. The particles adhere to the wafer the instant the plasma is extinguished, so the extinction of plasma is considered to be the cause of product defectiveness.

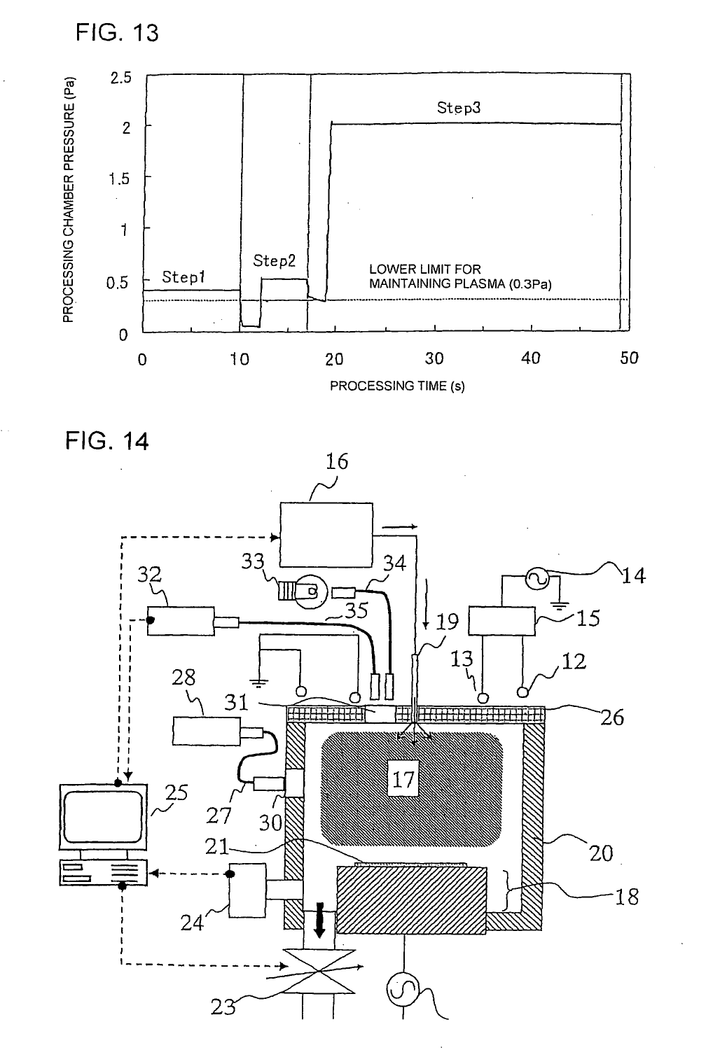

The variation of pressure within the processing chamber was examined to investigate the cause of extinction of plasma discharge immediately subsequent to the switching of gases. FIG. 13 shows the variation of the processing chamber pressure during etching. The processing chamber pressure was reduced to 0.3 Pa or lower immediately subsequent to switching steps. From the result of FIG. 5, it has been discovered that plasma discharge cannot be maintained when the processing chamber pressure is reduced to 0.3 Pa or lower. Therefore, it is presumed that the pressure reduction immediately subsequent to switching steps is the cause of plasma extinction. As a result of investigation, it has been discovered that the reduction in pressure is caused by the flow rate falling to 0 sccm immediately subsequent to switching gases. According to the present apparatus, the system automatically adjusts the pressure via the pressure controlling variable valve 23, but in the state where the flow rate is 0 sccm, the desired pressure could not be maintained and the processing chamber pressure dropped significantly.

In embodiment 3 of the present invention, the method for switching gases is improved in order to solve the above-mentioned problem. In order to prevent the gas flow rate from dropping to 0 sccm at the start of each step, it is necessary to consider the time required for switching gases and to perform the switching of valves a few seconds prior to the end point determination and to have the gas of the subsequent step supplied to the gas exhaust line. However, according to an ordinary end point determination using emission spectroscopy, it is difficult according to the end point determination timing to predict the end point in advance.

Therefore, according to embodiment 3 of the present invention, in addition to the emission spectroscopy system for determining the end point, an interference film thickness meter is disposed, and the timing of end point determination is predicted using the interference film thickness meter based on the time variation of residual film of the etched film. The structure of such etching apparatus is shown in FIG. 14. In this apparatus, a portion of the dielectric window 26 made of alumina and facing the wafer 21 is formed as a quartz window 31. Further, the apparatus includes a light source 33 for irradiating light to the wafer 21 and a spectroscopy system 32 for analyzing the reflection from the wafer 21. Further, the light source 33 and the quartz window 31 are connected via an optical fiber 34 so as to introduce the light from the light source 33 into the processing chamber, and the quartz window 31 and the spectroscopy system 32 are connected via an optical fiber 35 so as to introduce the reflected light to the spectroscopy system 32. According to this system, when the film thickness of the film subjected to etching on the wafer 21 is varied, the residual film thickness can be detected by the change in intensity of the reflection due to interference.

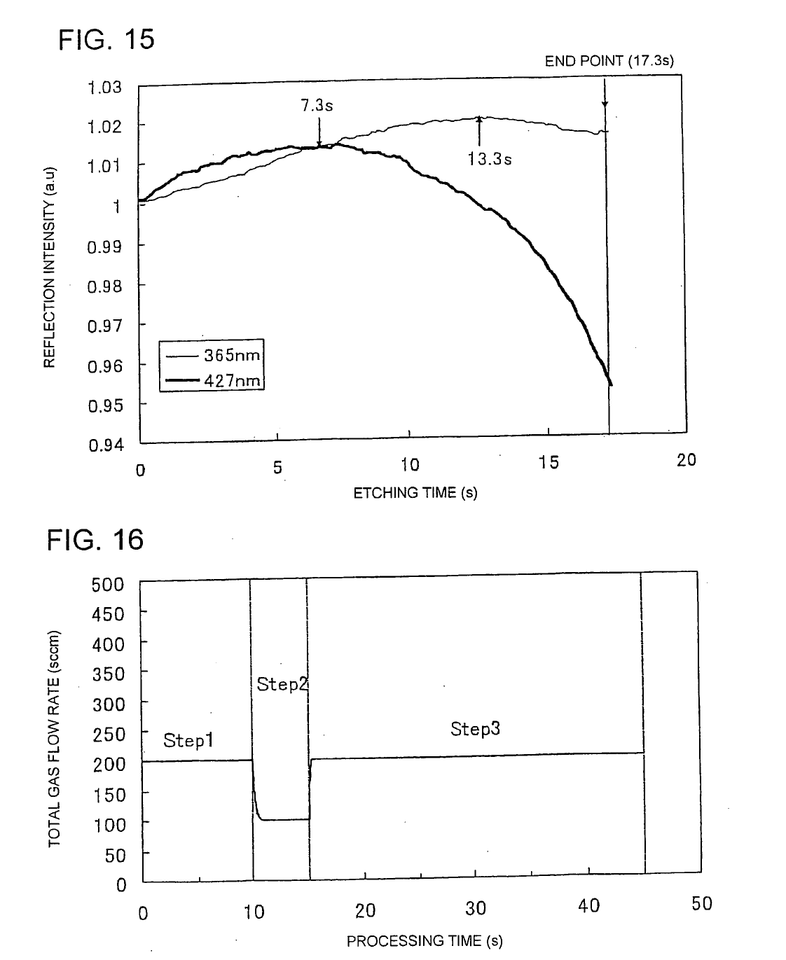

FIG. 15 shows the result of monitoring the time variation of reflection intensity of wavelengths 365 nm and 427 nm with respect to the gate etching process of a memory device. The reflection with a wavelength of 427 nm reaches its peak after 7.3 seconds, and thereafter, gradually decreases. On the other hand, the reflection with a wavelength of 365 nm reaches its peak after 13.3 seconds, and thereafter, gradually decreases. The end point is 17.3 s. In the actual mass production, the reflection intensity and etching end point are dispersed, but the waveforms are of similar forms. Therefore, based on an etching time t1 in which the 365 nm waveform reaches its peak and an etching time t2 in which the 427 nm waveform reaches its peak, an end point time t3 can be predicted using expression 1.

$${t}_{3} = \frac{17.3}{13.3 - 7.3} ( {t}_{2} - {t}_{1} ) \qquad [ Expression 1 ]$$

For example, in an example in which the time required for the gas flow to stabilize from the initial time the gas is supplied to the gas exhaust line is 2 seconds, the just etch time t3 is predicted based on expression 1, and the gas used in the subsequent step is started to be supplied to the exhaust line 2 seconds prior to the predicted time t3. Thereafter, when the time has reached the end point, the valves are switched so as to switch the processing gases. FIG. 16 shows the time variation of flow rate when the present system is applied to the three-step etching shown in FIG. 6.

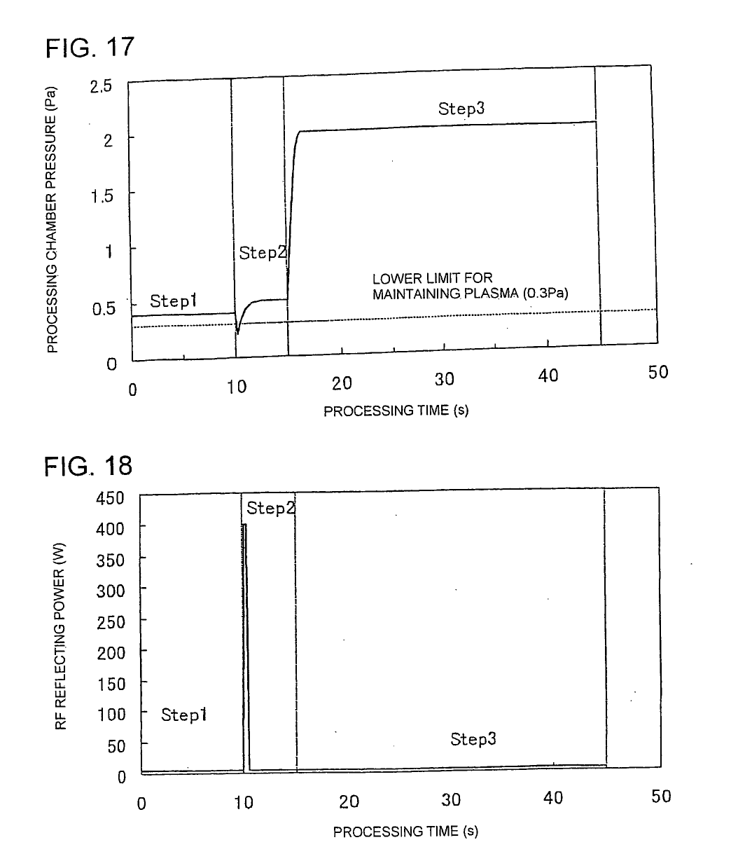

According to this arrangement, the system enables to have the gas flow rate reach the desirable flow rate smoothly after switching steps. The time variation of pressure at this time is shown in FIG. 17. It shows that the present system enables to overcome the problem of significant drop in pressure during switching of steps. Other than the fact that the pressure was decreased immediately after step 1 due to undershoot, the pressure varied smoothly.

FIG. 18 shows the variation of reflecting power at this time. The reflecting power is only significantly increased due to extinction of plasma for an instant immediately subsequent to step 1, and the increase in reflecting power is no longer seen immediately subsequent to step 2. The product defect rate due to particles when performing continuous discharge using the present method was reduced to 40% from 70% in the case of intermittent discharge.

As described, embodiment 3 of the present invention enables to reduce the drop in pressure during switching of steps by using the gas switching system of FIG. 9 and also based on the prediction of end point time using an interference film thickness meter or the like equipped with a light source 33 and a spectroscopy system 32 shown in FIG. 14. Therefore, the present embodiment effectively reduces product defects caused by particles by preventing unstable discharge during continuous discharge.

### Embodiment 4

According to embodiment 3, though instantaneously, the pressure dropped to 0.2 Pa and the plasma was extinguished immediately subsequent to step 1. Therefore, the effect of reduction of product defects during continuous discharge may not be sufficient. Therefore, the inventors investigated a method for reducing the drop in pressure immediately subsequent to step 1.

Upon comparing step 2 with step 1, the pressure is substantially the same but the flow rate is reduced to half. It has been discovered that the undershoot of pressure was caused by the slow response in pressure control, which makes it impossible to follow the rapid decrease of flow rate when transiting steps. In order to solve the problem of this undershoot, embodiment 4 of the present invention introduced a method to vary the gas flow rate in a stepwise manner.

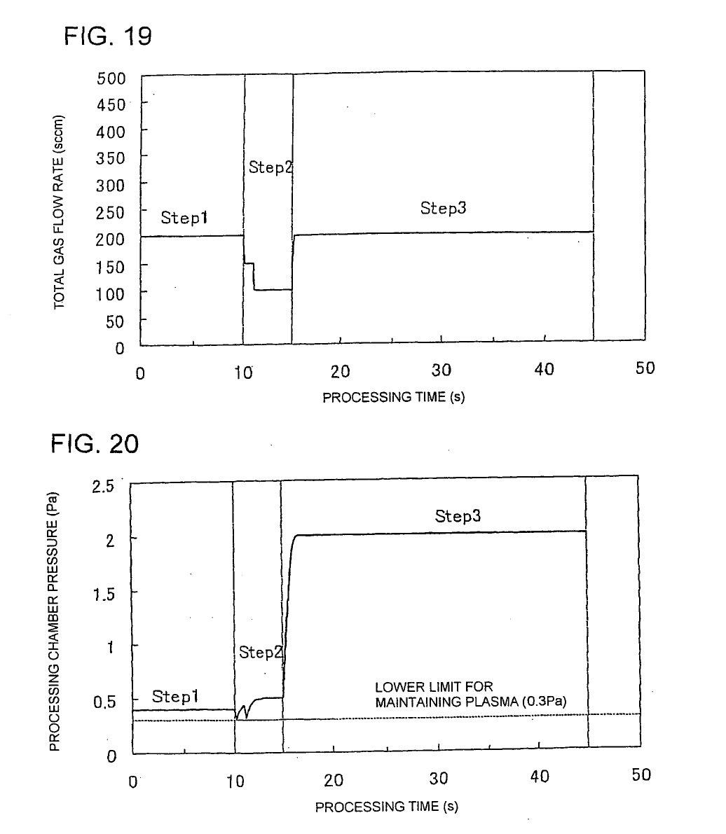

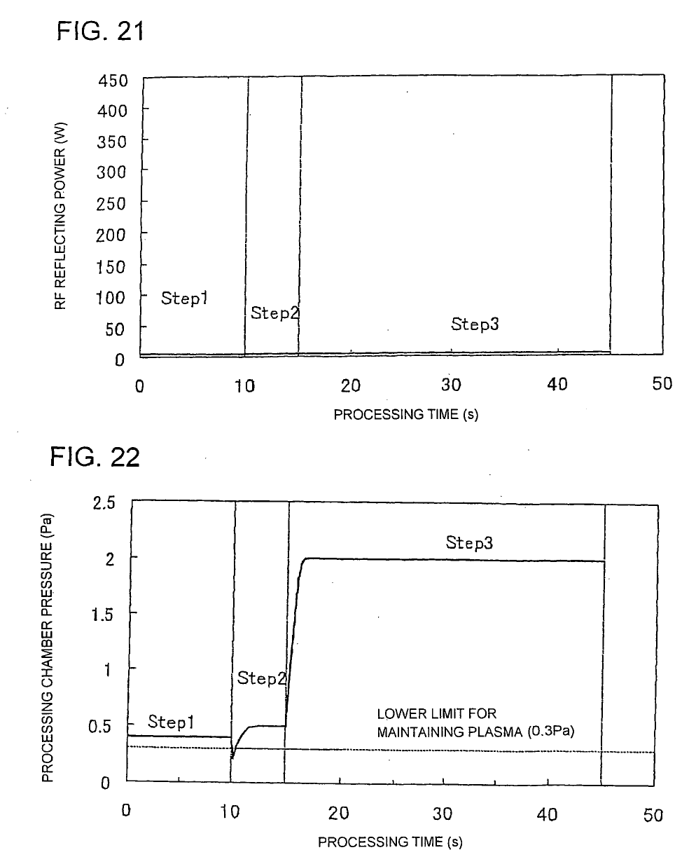

As shown in FIG. 19, the flow rate of MFC 112 was set to 150 sccm only for 1.0 s immediately subsequent to step 2, and thereafter, the flow rate was reduced to 100 sccm. The change in pressure according to this example is shown in FIG. 20. By reducing the gas flow rate in a stepwise manner, the undershoot of pressure was reduced, and the pressure did not drop to 0.3 Pa or lower. The change in reflecting power of this example is shown in FIG. 21. As shown, the phenomenon of reflecting power being increased by extinction of plasma no longer occurs. The product defect rate caused by particles according to this example is significantly reduced to 4%.

As described, according to embodiment 4 of the present invention, the undershoot of pressure caused by the difference in flow rate between step 1 and step 2, which could not be solved by the gas flow rate switching method of embodiment 3, could be suppressed by setting the flow rate at the start of step 2 to an intermediate flow rate between the flow rates of steps 1 and 2. According to this system, plasma will not be extinguished during switching of steps even when performing continuous discharge, and the product defects caused by particles can be cut down significantly.

### Embodiment 5

Embodiment 5 of the present invention introduces a method to suppress the undershoot of embodiment 3 by enhancing the pressure control performance. By improving the response speed of the pressure control variable valve 23, the time required for opening and closing the valve was cut down from 1 s to 0.5 s. The result is shown in FIG. 22. It can be seen that the mere improvement of open/close speed of the pressure controlling variable valve 23 was not effective in reducing undershoot.

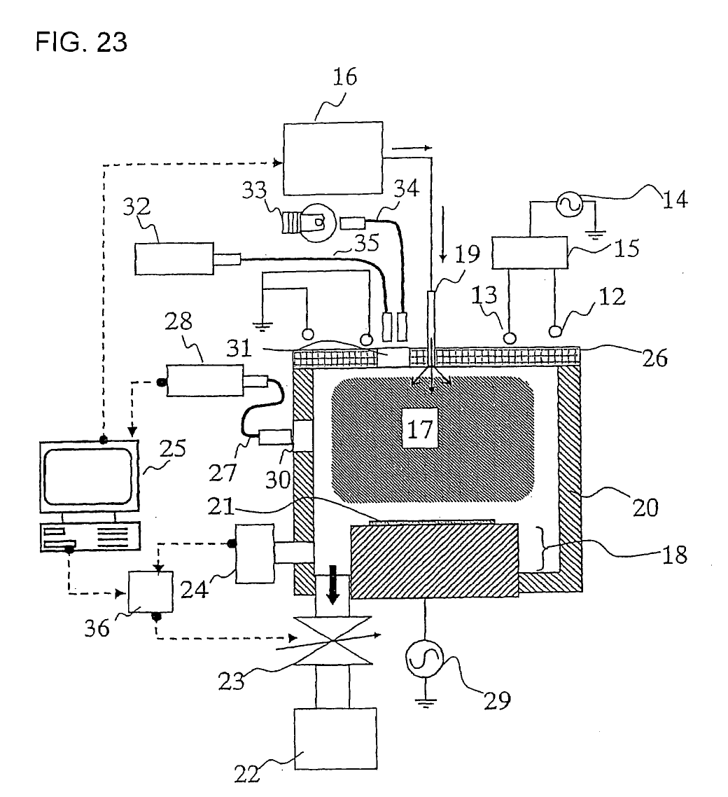

Therefore, the present inventors examined the effect of control cycles. According to the arrangement of embodiments 1 through 4, the computer 25 controls not only the pressure control variable valve 23 but the overall etching system. Therefore, there are many I/O interruptions from various units to the computer 25, so it is difficult to reduce the control cycle to 0.2 s or shorter. Therefore, according to embodiment 5 of the present invention, as shown in FIG. 23, a microcomputer 36 dedicated to controlling pressure is disposed, and the control cycle is shortened by changing the system so that the computer 25 only instructs the pressure setup value to the microcomputer 36.

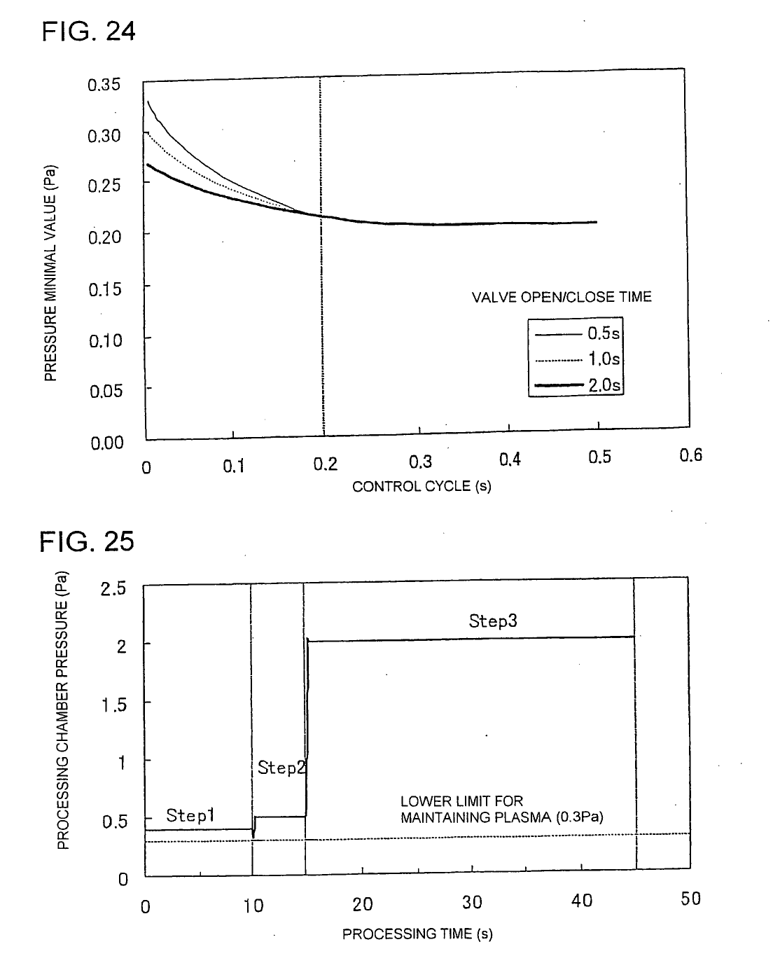

FIG. 24 shows the result of examining the minimal value of pressure when the control cycle was varied from 0.2 s to 0.01 s. In the area where the control cycle is equal to or greater than 0.2 s, the minimal value of pressure will not be varied even if the open/close speed of pressure controlling variable valve 23 is improved. On the other hand, in the area where the control cycle is smaller than 0.2 s, the minimal value of pressure can be increased by improving the open/close speed of the pressure controlling variable valve 23.

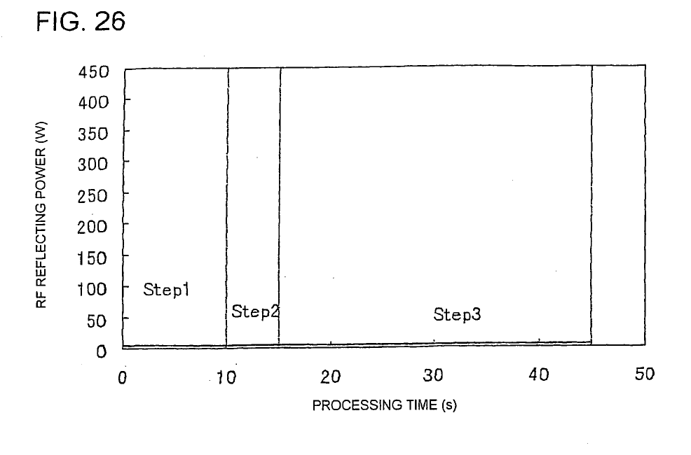

Therefore, it has been discovered that in order to reduce undershoot, it is effective to reduce the control cycle to below 0.2 s and improve the open/close speed of the pressure controlling variable valve 23. FIG. 25 shows the change in pressure when the control cycle is set to 0.01 s and the open/close time of the pressure controlling variable valve 23 is set to 0.5 s. According to this example, the undershoot immediately subsequent to step 1 is reduced, and the processing pressure did not drop to or below 0.3 Pa. FIG. 26 shows the variation of reflecting power according to this example. The phenomenon of the reflecting power being increased due to plasma extinction did not occur. The product defect rate caused by particles according to this example was significantly reduced to 4%.

As described, according to embodiment 5 of the present invention, the undershoot of pressure caused by the change in flow rate between step 1 and step 2, which could not be solved by the gas flow rate switching system of embodiment 3, could be reduced by using a dedicated microcomputer 36 for controlling pressure, setting the control cycle of pressure to 0.2 s or below, and improving the open/close speed of the valve. According to embodiment 5 of the present invention, plasma extinction during transition of steps will no longer occur even when performing continuous discharge, and the product defect caused by particles can be reduced significantly.

### Embodiment 6

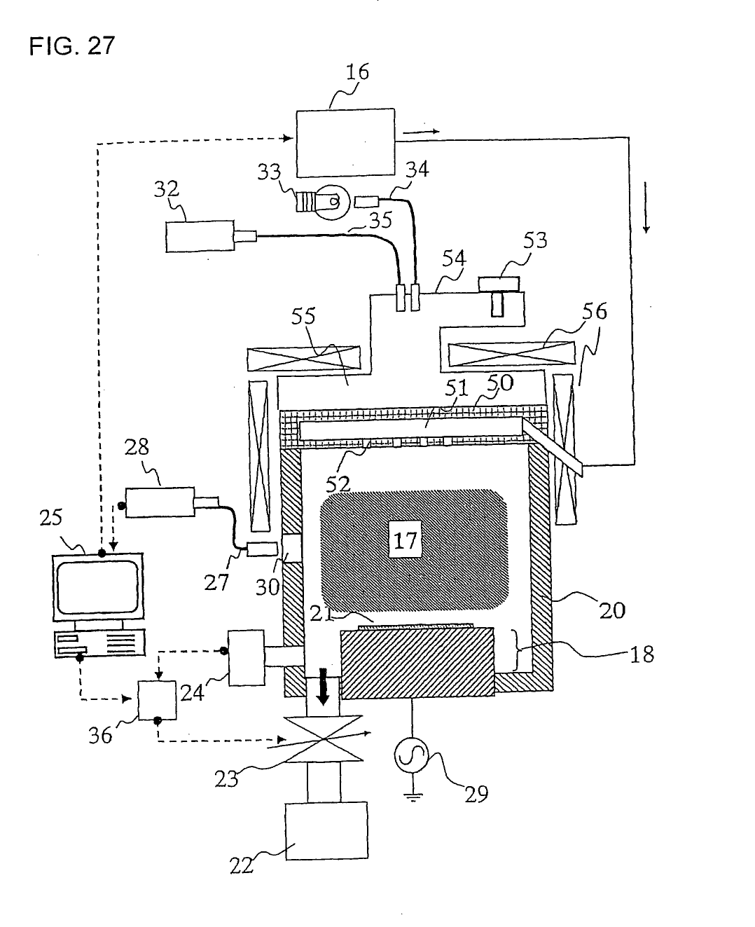

According to embodiment 6 of the present invention, the gas switching system and the pressure control method of embodiment 5 is applied to a microwave etching apparatus. The structure according to this embodiment is shown in FIG. 27. In this apparatus, the etching gas supplied from a gas supply unit 16 passes through a gas reservoir 51 formed inside a dielectric window 50 made of quartz, and introduced through a plurality of holes formed to the wall of the dielectric window 50 facing the vacuum pressure chamber into the vacuum processing chamber. Further, microwaves generated by a magnetron 53 are passed through a waveguide 54, a cavity resonance unit 55 and the dielectric window 50 to be supplied into the vacuum processing chamber, and by the interaction between the microwaves and the magnetic field generated by the coil 56, plasma 17 is generated in the processing chamber. In addition, the inner volume of the vacuum processing chamber is set to 150 L (liters) which is relatively large, so as to enhance the stability of pressure control. The other structures are equivalent to the apparatus of embodiment 5.

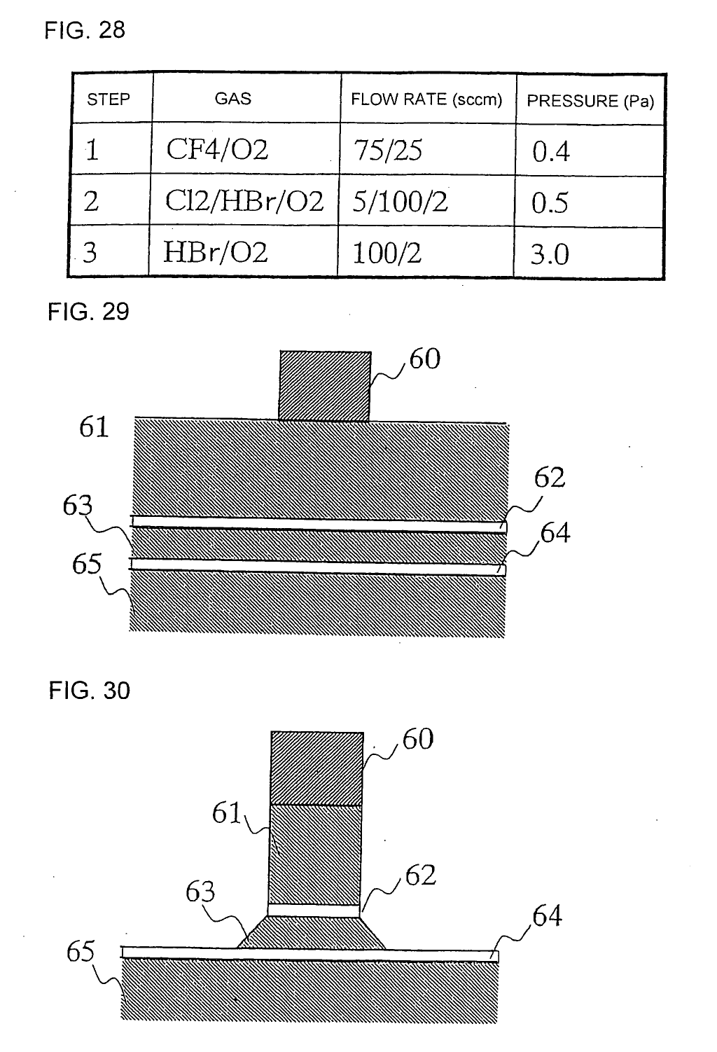

This apparatus was used to subject a sample having the structure illustrated in FIG. 29 to a three-step etching process shown in FIG. 28. In the present etching process, polysilicon 61, silicon oxide film 62 and polysilicon 63 are etched along a resist pattern mask 60, so that the silicon oxide film 64 and the substrate silicon 65 remain. First, in step 1, the polysilicon 61 and the silicon oxide film 62 are etched. In the second step, the polysilicon 63 is etched until the silicon oxide film 64 is exposed.

According to the process configuration of this process, the polysilicon 63 is tapered as shown in FIG. 30. In the third step, the bottom portion of the tapered configuration is removed through etching. At this time, a high pressure condition with a slow etching speed for silicon oxide film is used so as not to etch the silicon oxide film 64.

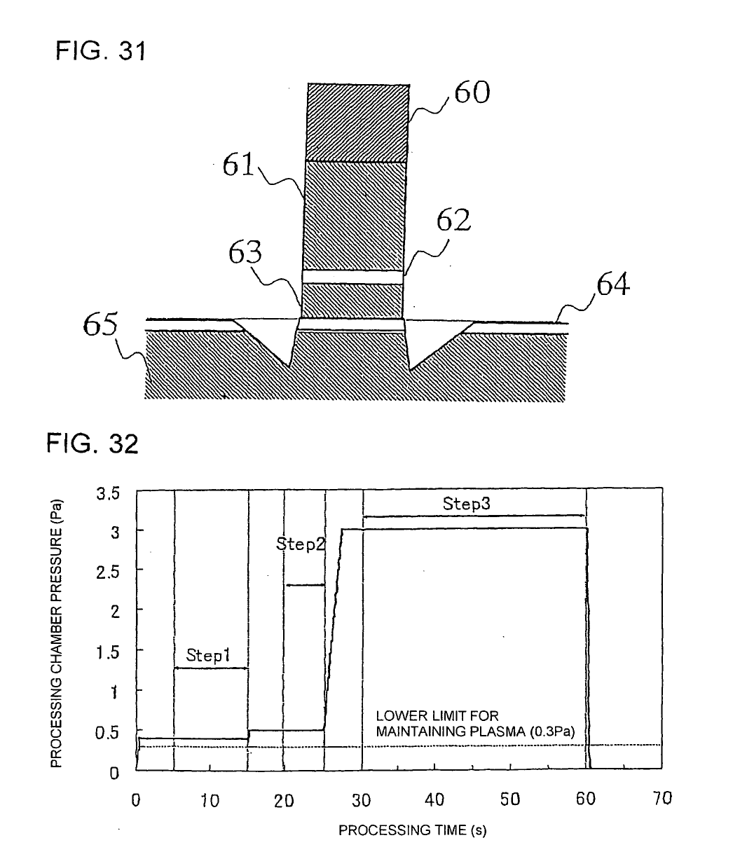

We will now compare the process configurations of wafers processed by two methods, one method with intermittent discharge and the other method with continuous discharge. According to the processing method adopting intermittent discharge, a sufficient thickness of silicon oxide film 64 remained, but on the other hand, according to the method adopting continuous discharge, as shown in FIG. 31, the silicon oxide film 64 was gone and a portion of the substrate silicon 65 was etched deeply.

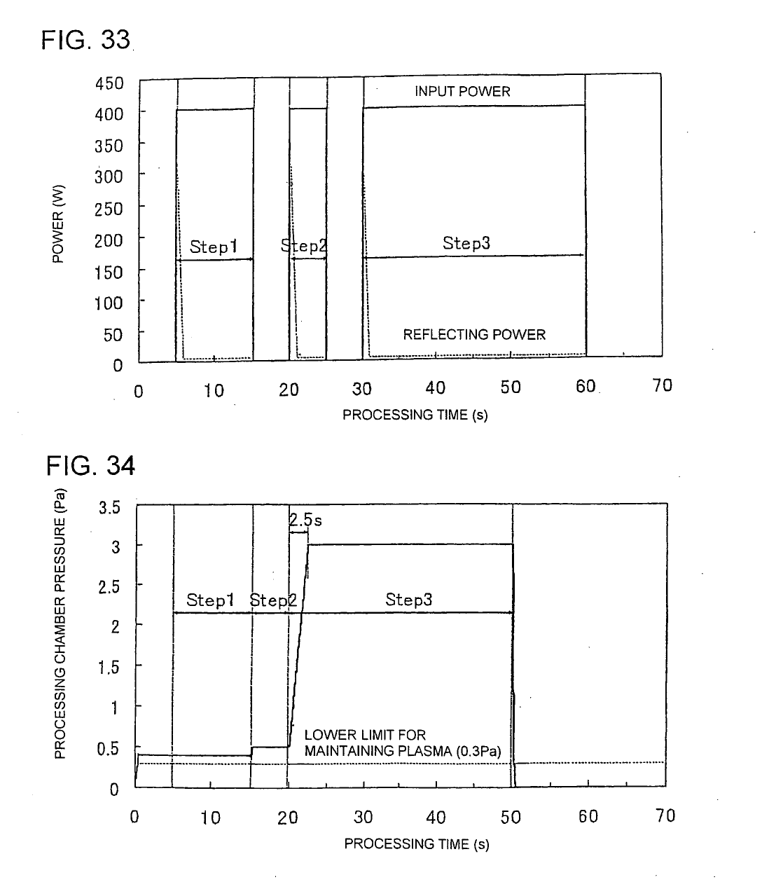

The cause of such difference was examined. The change in gas pressure according to the intermittent discharge method is shown in FIG. 32, and the change in microwave supply power and reflecting power according to the intermittent discharge method is shown in FIG. 33. In the intermittent discharge process, a period of time in which no microwave power is supplied is provided for 5 seconds at the start of each step so that the etching process is performed only during the periods of time where the pressure is stable.

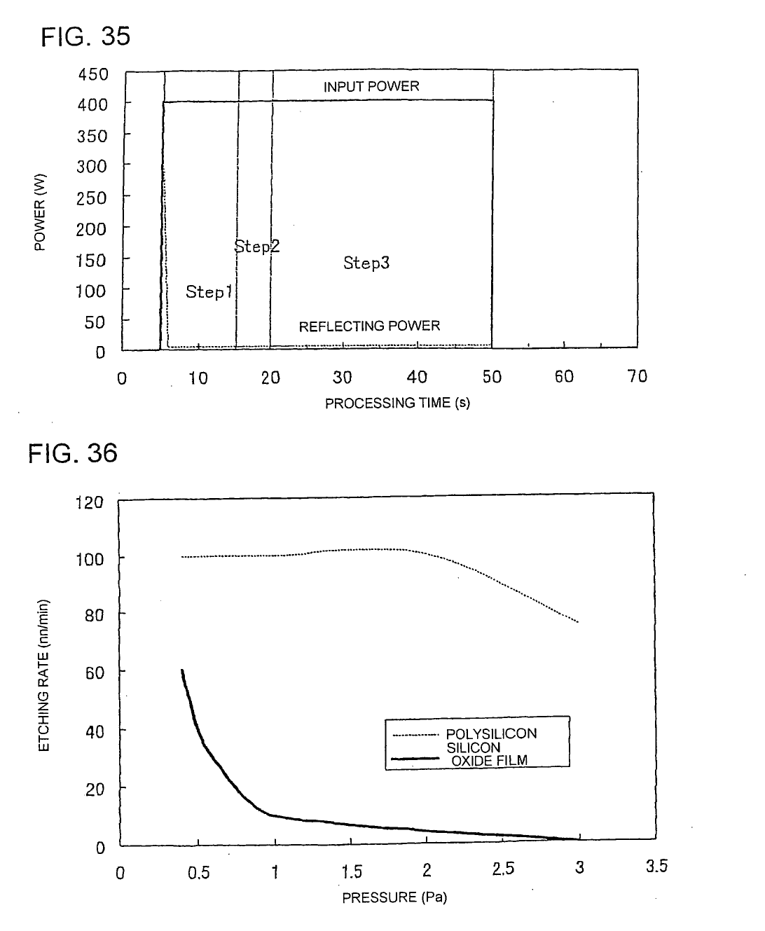

On the other hand, the change in gas pressure according to the continuous discharge method is shown in FIG. 34, and the change in microwave supply power and reflecting power according to the continuous discharge method is shown in FIG. 35. In this case, the microwave power was supplied continuously until the etching process is completed excluding the first 5 seconds. Therefore, the etching process is performed even during the time the pressure is varied. Especially at the start of step 3, the period of time in which the pressure is gradually increased from 0.5 Pa to 3 Pa lasts for approximately 2.5 seconds. Therefore, it is necessary to consider the etching process performed during that period of time.

FIG. 36 shows etching rates of polysilicon and silicon oxide film under the gas conditions of step 3 with the pressure changed from 0.4 Pa to 3 Pa. It is shown in the drawing that when the pressure is 3 Pa, the etching rate of silicon oxide film is substantially 0 nm/min, whereas when the pressure is reduced, the etching rate of silicon oxide film is increased, and when the pressure is around 0.5 Pa, the etching rate reaches as high as approximately 40 nm/min, at which time the selectivity with silicon is greatly deteriorated. Accordingly, it is assumed that when the thickness of the silicon oxide film 64 is small, the silicon oxide film 64 is etched and removed during the 2.5 seconds after step 3 is started before the pressure reaches 3 Pa.

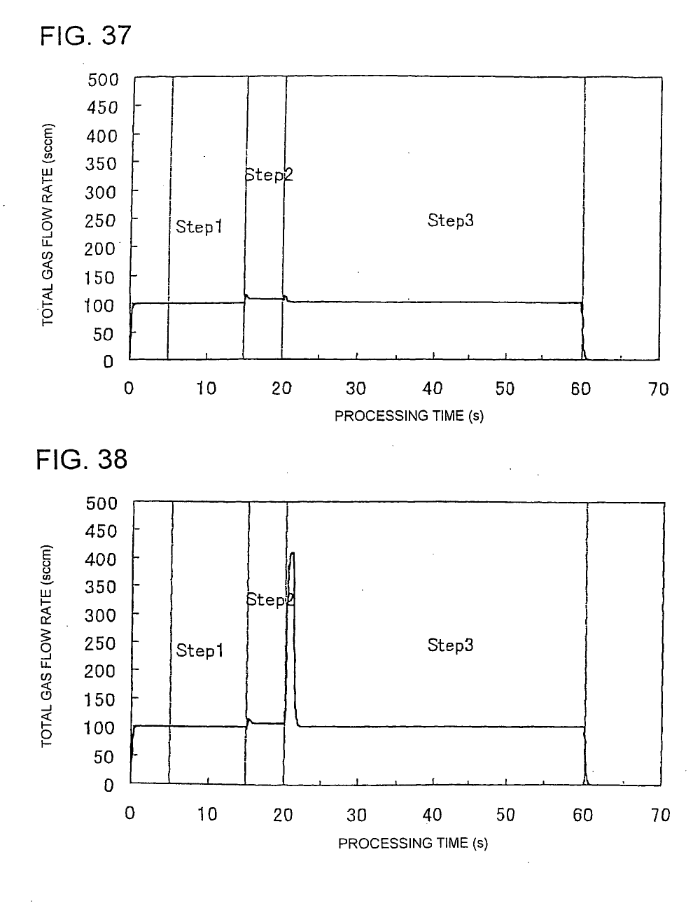

Therefore, the present inventors have considered a method for reducing the time required for the initial rise of pressure. The initial rise time of pressure is substantially proportional to the inner volume of the processing chamber and inversely proportional to the gas flow rate. Therefore, embodiment 6 of the present invention introduced a method to increase the total gas flow rate at the start of step 3 to be greater than the normal gas flow rate, and thereafter, return the same to the normal gas flow rate. The normal total gas flow rate is 100 sccm, which is substantially the same in all the steps as shown in FIG. 37, but according to embodiment 6 of the present invention, the gas flow rates of HBr (hydrogen bromide) and O2 (oxygen) are increased for one second at the start of step 3 to four times the normal gas flow rates, which are 400 sccm and 8 sccm, respectively, and thereafter, returned to the normal flow rates.

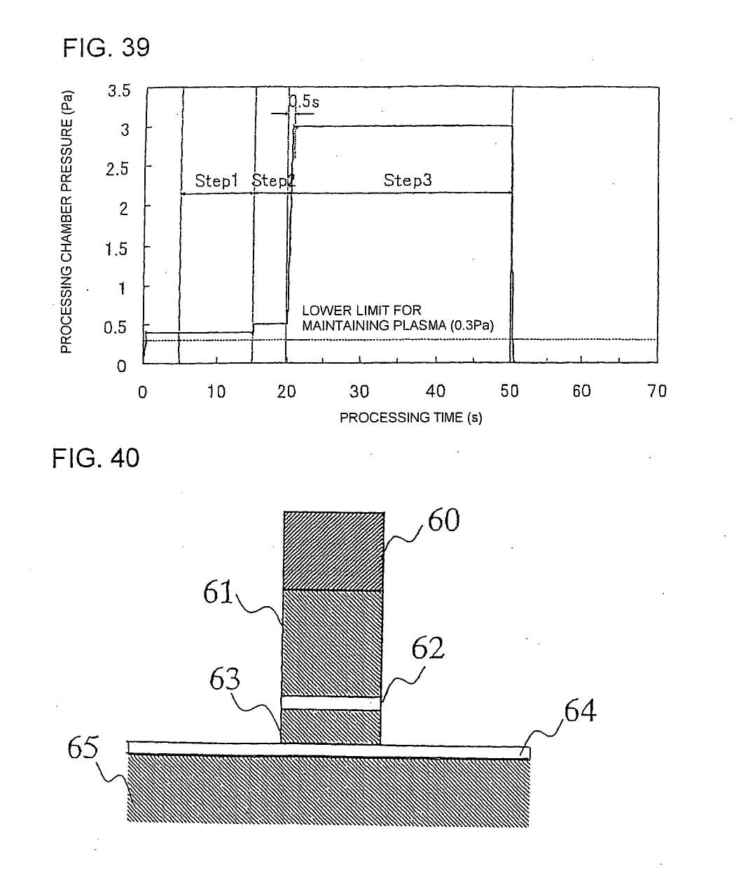

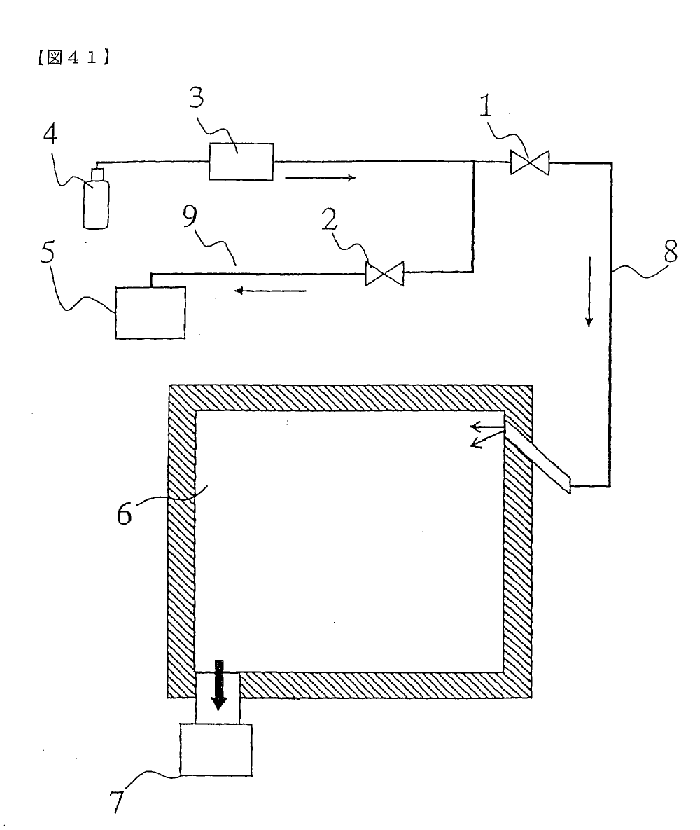

The change in pressure at this time is shown in FIG. 39. The time required for the pressure to reach 3 Pa was shortened to 0.5 seconds, and the pressure fluctuation during the time when the gas flow rate is returned from four times the normal value to the normal value was suppressed to an extremely small level. By etching the wafer shown in FIG. 29 using this method, as shown in FIG. 40, the residual film thickness or processed configuration of the silicon oxide film was substantially equivalent to that of the wafer processed by the intermittent discharge method.

As described, according to embodiment 6, if it is necessary to increase the pressure when transiting from step 1 to step 2, the target pressure value can be realized in a shorter time by increasing the gas flow rate at the start of step 2 to a value greater than the desired value while maintaining a constant gas flow ratio. By adopting this method, it becomes possible to achieve a processing property equivalent to that obtained by intermittent discharge even when performing continuous discharge.

What is claimed is:

1. A plasma etching apparatus having a processing chamber and a gas supply unit for supplying processing gases via a plurality of steps, for etching a substrate by discharging the processing gases; the apparatus comprising:
a determination unit for determining the timing for switching conditions for the plurality of steps; and
a control unit for controlling flow rates and pressures of the processing gases by operating the gas supply unit based on a timing determined by the determination unit so that the processing gases supplied from the gas supply unit do not fall to or below a predetermined pressure subsequent to switching steps.

2. The plasma etching apparatus according to claim 1, further comprising:
an inner antenna coil and an outer antenna coil for supplying power for generating plasma from the processing gases; wherein
power is supplied only from the outer antenna coil subsequent to switching steps.

3. The plasma etching apparatus according to claim 1, wherein
the gas supply unit comprises exhaust gas lines corresponding to each of the plurality of gas supply lines, and upon switching steps, the control unit opens the exhaust gas line of the subsequent step and sets the gas flow rate to a desired value, and thereafter switches valves so as to introduce the gas having a stable flow rate to the processing chamber.

4. The plasma etching apparatus according to claim 1, wherein
the control unit monitors the residual film thickness of the substrate, and based on the monitored data, predicts the timing for switching conditions.

5. The plasma etching apparatus according to claim 1, wherein
the control unit sets the flow rate of gas in the exhaust gas line of the gas supply unit to a desirable value at a predetermined period of time prior to the timing for switching conditions, and thereafter, switches the valve at the timing for switching conditions so as to introduce the gas having a stable flow rate to the processing chamber.

6. The plasma etching apparatus according to claim 1, wherein
when the flow rates of gases according to the conditions for the current step and the conditions for the subsequent step differ, upon starting the subsequent step, the control unit sets the gas flow rate of the gas supply unit to an intermediate value between the gas flow rate for the current step and the gas flow rate for the subsequent step and gradually reduces the gas flow rate.

7. The plasma etching apparatus according to claim 1, further comprising
a second control unit for controlling pressure, and the second control unit has a control cycle set to a smaller value than the predetermined control cycle, and an increased open/close speed of a pressure controlling variable valve.

8. The plasma etching apparatus according to claim 1, further comprising
a plasma generating unit for supplying RF power to the inner antenna coil and the outer antenna coil and generating inductively coupled plasma.

9. The plasma etching apparatus according to claim 1, wherein
the control unit increases a total gas flow rate at the start of a step for etching and removing a bottom portion of a tapered configuration of the substrate so as to reduce the initial rise time of pressure.

10. A plasma etching apparatus for etching a substrate by generating plasma from a mixed gas, comprising:
a vacuum processing chamber;
a gas supply unit for supplying the mixed gas composed of a plurality of gases into the vacuum processing chamber;
a first exhaust apparatus; and
a variable conductance valve disposed between the first exhaust apparatus and the vacuum processing chamber for controlling the pressure in the vacuum processing chamber; wherein
the gas supply unit is designed so that each gas is supplied via respective mass flow controllers to the vacuum processing chamber, and the mass flow controllers have first valves disposed respectively between the vacuum processing chamber, gas bypath pipes branching respectively from portions between the mass flow controllers and the first valves to be connected to a second exhaust apparatus, and second valves disposed on the bypath pipes;
the plasma etching apparatus further comprising a mechanism for monitoring a residual film thickness of the substrate during the etching process, and a control unit for determining based on the mechanism the timing for switching conditions of the gases and controlling the opening or closing timing of the first and second valves of the gas supply unit.

11. A plasma etching method using a plasma etching apparatus having a processing chamber and a gas supply unit for supplying processing gases via a plurality of steps, for etching a substrate by discharging the processing gases; the method comprising:
determining the timing for switching conditions for the plurality of steps; and
controlling flow rates and pressures of the processing gases by operating the gas supply unit based on a determined timing so that the processing gases supplied from the gas supply unit do not fall to or below a predetermined pressure subsequent to switching steps.

12. The plasma etching method according to claim 11, further comprising:
supplying power only from an outer antenna coil out of an inner antenna coil and an outer antenna coil so as to generate plasma from the processing gases.

13. The plasma etching method according to claim 11, wherein upon switching steps in the gas supply unit having gas exhaust lines corresponding to each of the plurality of gas supply lines, the exhaust gas line of the subsequent step is opened and the gas flow rate thereof is set to a desired value, and thereafter, the valves are switched so as to introduce the gas having a stable flow rate to the processing chamber.

14. The plasma etching method according to claim 11, further comprising
monitoring a residual film thickness of the substrate, and
predicting the timing for switching conditions.

15. The plasma etching method according to claim 11, further comprising
setting the flow rate of gas in the exhaust gas line of the gas supply unit to a desirable value at a predetermined period of time prior to the timing for switching conditions, and thereafter, switching the valve at the timing for switching conditions so as to introduce the gas having a stable flow rate to the processing chamber.

16. The plasma etching method according to claim 11, further comprising
if the flow rates of gases according to the conditions for the current step and the conditions for the subsequent step differ, setting the gas flow rate of the gas supply unit to an intermediate value between the gas flow rate for the current step and the gas flow rate for the subsequent step and gradually reducing the gas flow rate upon starting the subsequent step.

17. The plasma etching method according to claim 11, further comprising
setting a control cycle of a microcomputer dedicated to controlling pressure smaller than a predetermined cycle, thereby increasing open/close speed of a pressure controlling variable valve.

18. The plasma etching method according to claim 11, further comprising
supplying RF power to the inner antenna coil and the outer antenna coil and generating inductively coupled plasma.

19. The plasma etching method according to claim 11, further comprising
increasing a total gas flow rate at the start of a step for etching and removing a bottom portion of a tapered configuration of the substrate so as to reduce the initial rise time of pressure.

20. A plasma etching method for etching a substrate by generating plasma from a mixed gas, using a plasma etching apparatus comprising a vacuum processing chamber, a gas supply unit for supplying the mixed gas composed of a plurality of gases into the vacuum processing chamber, a first exhaust apparatus, and a variable conductance valve disposed between the first exhaust apparatus and the vacuum processing chamber for controlling the pressure in the vacuum processing chamber;
the method comprising:
determining a timing for switching conditions of respective gases using a mechanism for monitoring a residual film thickness of the substrate during the etching process: and
in response to the determined timing, controlling the opening and closing of first valves respectively disposed between a plurality of mass flow controllers of the gas supply unit and the vacuum processing chamber and second valves respectively disposed on a plurality of gas bypath pipes branching from a portion between the plurality of mass flow controllers and the first valves to be connected to a second exhaust apparatus.
